(19) United States
(12) Patent Application Publication
(10) Pub. No.: US 2026/0334243 A1
(43) Pub. Date: Oct. 22, 2026

(54) PREPARATION METHOD FOR POLYIMIDE VIA AND WAFER LEVEL SEMICONDUCTOR PACKAGING STRUCTURE

(71) Applicant: SJ Semiconductor(Jiangyin) Corporation, Jiangyin (CN)

(72) Inventors: Xiang LIU, Jiangyin (CN); Jiashan YIN, Jiangyin (CN); Zuyuan ZHOU, Jiangyin (CN); Xingtao XUE, Jiangyin (CN); Chengchung LIN, Jiangyin (CN)

(73) Assignee: SJ Semiconductor(Jiangyin) Corporation, Jiangyin, JS (CN)

(21) Appl. No.: 19/107,593

(22) PCT Filed: Jun. 1, 2023
(86) PCT No.: PCT/CN2023/097808

§ 371 Date: Feb. 28, 2025

(30) Foreign Application Priority Data
Sep. 2, 2022 (CN) 202211068622.9

(51) Int. Cl. H10W 70/05; H10W 70/66; H10W 70/695

(52) U.S. Cl. CPC H10W 70/095; H10W 70/66; H10W 70/695

(57) ABSTRACT

A method of preparing a polyimide via and a wafer-level semiconductor packaging structure comprises: S1: providing a substrate with metal pads on the surface; S2: forming a polyimide layer on the substrate; S3: forming a metal layer on the polyimide layer; S4: forming a pre-determined layer on the metal layer and a first pre-passage hole on the pre-determined layer; S5: etching the metal layer to form a second pre-passage hole; S6: etching the polyimide layer to form a third pre-passage hole; S7: removing all structures above the polyimide layer to form a polyimide hole in the polyimide layer. The invention avoids the problem of residues at the bottom of small-sized polyimide perforations, making the top and bottom profiles of polyimide perforations even, thus improving the yield. In the wafer-level semiconductor package, the smaller polyimide perforations enable more complex the product design, improving the chip performance.

### TECHNICAL FIELD

The present invention relates to the field of advanced semiconductor packaging technology, and in particular, relates to a method of preparing polyimide perforations and wafer-level semiconductor packaging structures.

### BACKGROUND

With the rapid development of electronic science and technology, miniaturization trend in microelectronics technology, the research and development on wafer-level packaging materials continue to advance. Benzocyclobutene (BCB) was selected as an early wafer-level packaging material, but it was gradually eliminated due to its low elongation at break, low tensile strength, and high process cost. Nowadays, Polyimide (PI) is a polymer material that has been widely used in aerospace, microelectronics, and other fields due to its excellent thermal stability, mechanical properties, chemical stability, dielectric properties, insulation, adhesion, and water resistance. Especially in advanced semiconductor packaging processes such as wafer-level packaging, polyimide has been used as one of the most important interlayer dielectric materials. As shown in FIGS. 1 to 3, in conventional prior art, polyimide perforations are usually prepared by coating, exposing, developing, and curing to connect the top and bottom redistribution layers (RDLs), but the profile of the polyimide perforations varies greatly from top to bottom in the layer, and the process is not refined, and residue will be present at the bottom of the perforations. Advanced semiconductor packaging technologies require smaller-sized polyimide perforations to improve chip performance, thus process optimization and improvement have to be provided.

In view of the above, it is necessary to provide a method of preparing polyimide perforations and semiconductor packaging structures, which avoids the problem of the presence of residues at the bottom of small-sized polyimide perforations, makes the top and bottom contours of the polyimide perforations basically consistent, and refines the preparation process, thereby improving the yield of the product and the chip performance.

### SUMMARY

In view of the drawbacks of the above-described techniques, the present invention provides a method of preparing polyimide perforations and wafer-level semiconductor packaging structures to avoid the problem of the residues presence at the bottom of small-sized polyimide perforations, making the top and bottom contours of the polyimide perforations even, and refining the preparation process, thereby improving the performance and the yield of the chips.

The present invention provides a method of preparing a polyimide perforation, the method comprises:

S1: provide a substrate with metal pads on the surface;

S2: forming a polyimide layer on the substrate, the top of the polyimide layer is above the metal pads;

S3: forming a metal layer on the polyimide layer;

S4: forming a pre-determined layer on the metal layer and forming a first pre-passage hole on the pre-determined layer, the first pre-passage hole being located vertically directly above the metal pads, the first pre-passage hole having an aperture size of less than or equal to 2 μm;

S5: etching the metal layer to form a second pre-perforation aligned to the first pre-perforation;

S6: aligned to the second pre-passage hole, etching the polyimide layer to form a third pre-passage hole, the third pre-passage hole being disposed vertically directly above the metal pads and in direct contact with the metal pads; and

S7: removing all structures above the polyimide layer to form polyimide perforations on the polyimide layer.

Optionally, the first pre-passage hole, the second pre-passage hole, and the third pre-passage hole have the same hole size.

Optionally, the step of forming the polyimide layer comprises: coating, exposing all, and curing.

Optionally, in step S4, the step of forming the preset layer comprises: first forming a patterned preset photoresist layer on the metal layer, the preset photoresist layer being disposed vertically directly above the metal pads, the preset photoresist layer having a diameter size of less than or equal to 2 μm; electroplating metal on the metal layer to form the preset layer, the preset layer filling in the gap between the preset photoresist layers, the preset layer being flush with the top of the preset photoresist layer; etching away all of the preset photoresist layers so as to form the first pre-passage hole at the location of the preset layer. The layer is flush with the top of the pre-determined photoresist layer; etching away all of the pre-determined photoresist layers so as to form the first pre-passage hole at the location of the pre-determined photoresist layer. Optionally, in step S4, the pre-determined layer is a photoresist layer, and the step of forming the pre-determined layer includes coating, exposing and developing, and etching the pre-determined layer to form the first pre-passage holes, the first pre-passage holes are located vertically directly above the metal pads, and the size of the holes of the first pre-passage holes is less than or equal to 2 μm, and in step S5, the formation of the second pre-passage holes also includes the step of removing the pre-determined layer.

Optionally, in step S4, the material of the pre-determined layer is polyimide, and the step of forming the pre-determined layer comprises coating, exposing, developing, and curing, whereby the first pre-passage hole is formed on the pre-determined layer, the first pre-passage hole is located vertically directly above the metal pads, and the hole size of the first pre-passage hole is less than or equal to 2 μm, and in step S5, the step of forming the second pre-passage hole further comprises removing the step of removing the pre-patterned layer.

Optionally, the material of the metal pads is one or a combination of two or more of aluminum, copper, and gold.

Optionally, the metal layer is a monolayer structure of an Al layer or a stacked structure of a Ti layer and a Cu layer.

Optionally, the method of forming the polyimide perforations is dry etching the polyimide layer.

The present invention also provides a method of preparing a wafer-level semiconductor packaging structure, the method of preparation comprising: a method of preparing a polyimide perforation as described in any one of the foregoing.

As described above, the polyimide perforations and the preparation method of wafer-level semiconductor packaging structure of the present invention have the following beneficial effects: the present invention avoids the problem of the existence of residues at the bottom of the small-sized polyimide perforations, makes the top and bottom contours of the polyimide perforations basically consistent, and refines the preparation process, thus improving the yield rate of the product; the present invention, in wafer-level semiconductor packaging, the smaller polyimide perforations can make the product design is more complex and detailed, which greatly improves the chip performance.

### BRIEF DESCRIPTION OF THE DRAWINGS

FIG. 1 shows a schematic diagram of the structure during coating by the existing method of preparing polyimide perforations.

FIG. 2 shows a schematic diagram of the structure during exposure during preparing polyimide perforations by the existing method.

FIG. 3 shows a schematic diagram of the polyimide perforations structure during developing and curing prepared by the existing method.

FIG. 4 shows a schematic flow chart of the method of preparing the polyimide perforations according to the present disclosure.

FIG. 5 shows a schematic diagram of the structure during step S1 by the method of preparing polyimide perforations according to the present invention.

FIG. 6 shows a schematic diagram of the structure during step S2 of the method of preparing a polyimide perforation according to the present invention.

FIG. 7 shows a schematic diagram of the structure during step S3 of the method of preparing polyimide perforations according to the present invention.

FIG. 8 shows a schematic diagram of the structure during step S4 of the method of preparing polyimide perforations according to the present invention.

FIG. 9 shows a schematic diagram of the structure presented in step S5 of the method for preparing polyimide perforations according to the present invention.

FIG. 10 shows a schematic diagram of the structure presented in step S6 of the method for preparing polyimide perforations according to the present invention.

FIG. 11 shows a schematic diagram of the structure presented in step S7 of the method of preparing a polyimide perforation according to the present invention.

FIG. 12 shows a schematic diagram of a structure during forming a pre-determined photoresist layer of step S4 of the method for preparing a polyimide perforation according to a specific embodiment of the present invention.

FIG. 13 shows a schematic diagram of a structure during forming a pre-determined layer step S4 of the method for preparing a polyimide perforation according to a specific embodiment of the present invention.

FIG. 14 shows a schematic diagram of the structure during removing the pre-determined layer in which the first pre-perforation is located of step S5 in the method for preparing polyimide perforations according to the specific embodiment of the present invention.

FIG. 15 shows a schematic diagram of a structure presented in a specific embodiment of step S4 of the method of preparing a polyimide perforation of the present invention in which a first pre-perforation is formed in a pre-determined polyimide layer.

FIG. 16 shows a schematic cross-sectional view of a structure after forming a second pre-passage hole aligned to the first pre-passage hole in FIG. 15.

### REFERENCE NUMERALS

10, a substrate; 20, a metal pad; 30, a polyimide layer; 40, a metal layer; 50, a pre-determined photoresist layer; 60, a pre-determined layer; 71, a first pre-passage hole; 72, a second pre-passage hole; 73, a third pre-passage hole; and 74, a polyimide hole.

### DETAILED DESCRIPTION OF THE PREFERRED EMBODIMENTS

The specific embodiments are described below to illustrate the implementation of the present disclosure, and those skilled in the art can easily understand other advantages and effects of the present disclosure from the content disclosed in this specification. The present disclosure can also be implemented or applied in other specific embodiments. The details provided in this description can be modified or altered in various ways based on different perspectives and applications without departing from the spirit of the present disclosure. As in the detailed description of the embodiments of the present invention, for the sake of illustration, the sectional drawings representing the structure of the device will not be partially enlarged in accordance with the general scale, and the schematic drawings are only examples, which shall not limit the scope of protection of the present invention herein.

For ease of description, spatial relationship terms such as “below,” “under,” “below,” “below,” “below,” “above,” “above,” “above,” and the like may be used herein to describe the relationship of one structure or feature shown in the accompanying drawings to other structures or features., “above,” “on,” and the like to describe the relationship of one structure or feature shown in the accompanying drawings to other structures or features. It will be appreciated that these spatial relationship terms are intended to encompass orientations of the device in use or operation other than those depicted in the accompanying drawings. Furthermore, when a layer is to be “between” two layers, it may be the only layer between the two layers, or there may be one or more intervening layers. The term “between . . . ” is used in this document to include both endpoint values. In the context of the present application, the described structure with the first feature “on top” of the second feature may include embodiments in which the first and second features are formed in direct contact or may include embodiments in which additional features are formed between the first and second features, such that the first and second features may not be in direct contact.

Refer to FIG. 1 through FIG. 16. It is to be noted that the illustrations provided in this embodiment only illustrate the basic concept of the present invention in a schematic manner so that the illustrations only show the components related to the present invention and are not drawn in accordance with the actual implementation of the number of components, shapes and sizes of the actual implementation of the components of the type, number and proportion of the actual implementation of the components may be an arbitrary change, and the layout of the components of the type may be more complex.

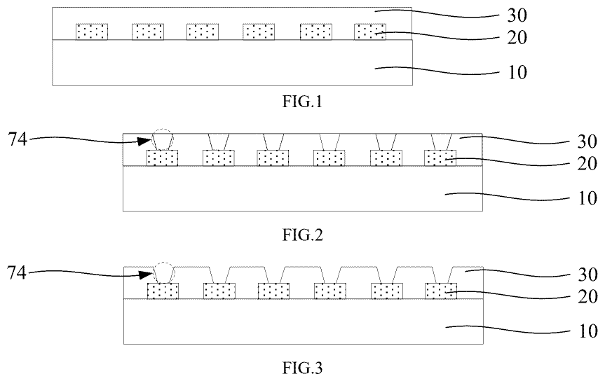

Polyimide is one of the most important interlayer dielectric materials in semiconductor packaging. As shown in FIGS. 1 to 3, a method for preparing polyimide perforations in the prior art is shown in FIGS. 1 to 3. The polyimide perforations are usually prepared mainly by the steps of coating (as shown in FIG. 1), exposure (as shown in FIG. 2), developing, and curing (as shown in FIG. 3), which connects the top and bottom redistribution layers. However, the contour of the polyimide perforations prepared by the existing technique varies greatly from top to bottom (as shown in FIG. 3), especially at the bottom of the perforations, where there are residues, which makes the dimensions of the top and bottom contours of the polyimide perforations inconsistent, and results in a low product yield.

Aligned to the above findings and after research and analysis, the inventor proposes a method of preparing polyimide perforations to solve the problem of residues at the bottom of the polyimide perforations, to make the top and bottom contours of the polyimide perforations basically consistent, and to fine-tune the preparation process so as to improve the yield of the product and also to greatly improve the performance of the chip. The method of preparing the polyimide perforations of this embodiment is described in detail below in connection with the accompanying drawings.

### Embodiment 1

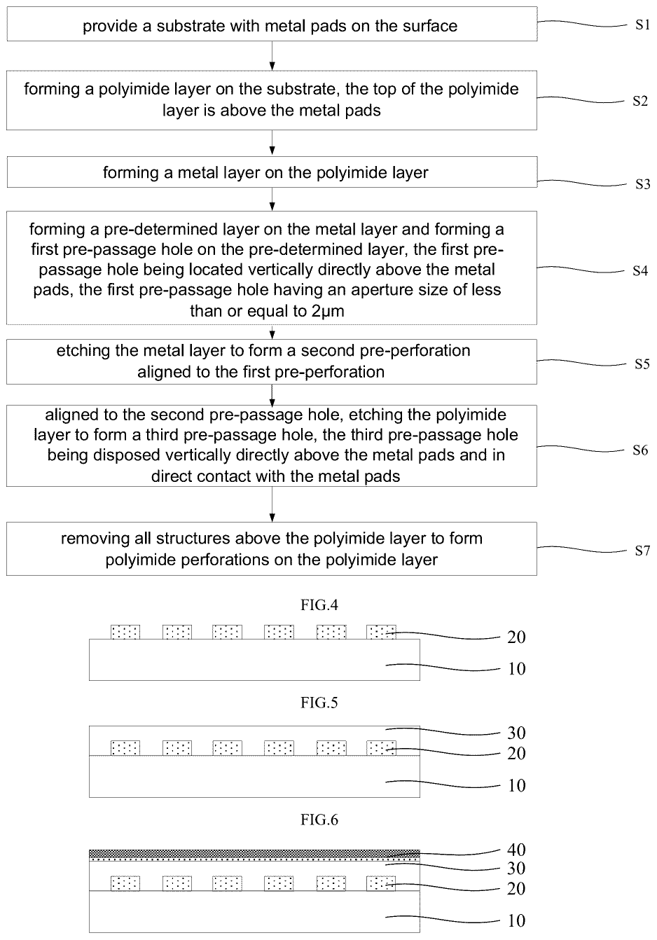

As shown in FIGS. 4 to 11, this embodiment provides a method of preparing a polyimide perforation, the method of preparing a polyimide perforation comprises the steps of:

S1: a substrate 10 having a metal pad 20 attached to the surface is provided;

S2: forming a polyimide layer 30 on the substrate 10, the top of the polyimide layer 30 is higher than the metal pad 20 in the vertical direction;

S3: forming a metal layer 40 on the polyimide layer 30;

S4: forming a pre-determined layer 60 on the metal layer 40 and forming a first pre-passage hole 71 in the pre-determined layer, the first pre-passage hole 71 being located vertically above and aligned to the metal pad 20, and the first pre-passage hole 71 has a hole size less than or equal to 2 μm;

### S5: Etching the Metal Layer 40 to Form a Second Pre-passage Hole 72 Aligned to

the first pre-passage 71;

S6: aligned to the second pre-passage hole 72, etch the polyimide layer 30 to form a third pre-passage hole 73, the third pre-passage hole 73 being located vertically above and in direct contact with the metal pad 20;

S7: Removing all structures above the polyimide layer 30 to form polyimide hole 74 on the polyimide layer 30.

This embodiment avoids the problem of residues at the bottom of the polyimide hole 74 of small size, making the upper and lower contours of the polyimide hole 74 basically the same, and refining the preparation process, thus improving the yield of the product; this embodiment in wafer-level semiconductor packaging, smaller the polyimide hole 74 can make the product design more complex and detailed, and greatly improves the performance of the chip.

Referring to FIGS. 4 through 16, the present embodiments are further described below in connection with the accompanying drawings.

As shown in FIGS. 4 and 5, as an example, step S1 is first performed to provide the substrate 10 with metal pads 20 attached to the surface.

As an example, the substrate 10 is one of a glass substrate, a metal substrate, a semiconductor substrate, a polymer substrate, and a ceramic substrate, and it is preferred in this embodiment to use a glass layer, the glass layer being less costly and capable of reducing the difficulty of the subsequent stripping process. As an example, the material of the metal pad 20 is one or a combination of two or more of aluminum, copper, and gold. The present embodiment does not impose any limitation on the thickness of the substrate 10 and the metal pad 20, which may be set according to actual needs, as long as the above requirements are met.

As shown in FIGS. 4 and 6, as an example, step S2 is then carried out to form a polyimide layer 30 on the substrate 10, the top of the polyimide layer 30 is higher than the metal pad 20.

As an example, the steps of forming the polyimide layer 30 include: coating, full exposure, and curing. It should be noted herein that the steps for forming the polyimide layer 30 in the present embodiment are different from those in the prior art, in which the polyimide perforations are usually prepared mainly through the steps of coating, exposing, developing and curing, that is to say, the polyimide perforations will be prepared together with the formation of the polyimide layer, which is already patterned during the step of exposing to form the prototype of the polyimide perforations, and then through the steps of The polyimide layer with polyimide perforations is formed by developing and curing. In this embodiment, a polyimide is coated on the substrate 10, all of which is exposed coated with polyimide and cured to shape to form the polyimide layer 30, when the polyimide layer 30 is solid and does not contain the polyimide hole 74.

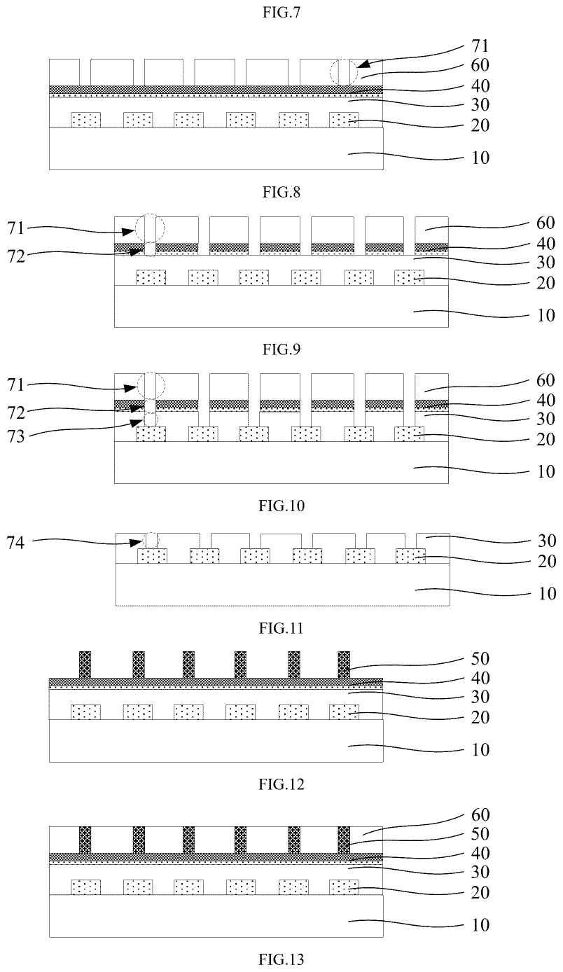

As shown in FIGS. 4 and 7, as an example, step S3 is then performed to form a metal layer 40 on the polyimide layer 30.

As an example, the metal layer 40 is a single-layer structure of Al layers or a stacked structure of Ti and Cu layers, with only the stacked structure of Ti and Cu layers shown in FIG. 7. In this embodiment, the method of forming the metal layer 40 is the sputtering process method, when the metal layer 40 is a single layer structure of Al layer, i.e., sputtering an Al layer on the polyimide layer 30; when the metal layer 40 is a stacked structure of Ti layer and Cu layer, i.e., sputtering a Ti layer and then a Cu layer on the polyimide layer 30 to form a stacked metal layer Ti/Cu layer. The Al layer and the Ti/Cu layer are both nanoscale metal layers, the thickness of which can be set according to actual needs and is not limited herein. The metal layer 40 is formed in this step in order to ensure that the range of apertures to be etched remains the same during subsequent longitudinal etching of small sizes, while the metal layer 40 is sandwiched between the polyimide layer 30 and the pre-determined layer 60 in order to facilitate removal of the pre-determined layer 60 without adhesion to the polyimide layer 30 when the pre-determined layer 60 is removed.

As shown in FIGS. 4 and 8, as an example, step S4 is then carried out to form a pre-determined layer 60 on the metal layer 40, and to form a first pre-passage hole 71 on the pre-determined layer 60, the first pre-passage hole being located vertically directly above the metal pad 20, and aperture dimensions of the first pre-passage hole 71 being less than or equal to 2 μm.

The method of forming the pre-determined layer 60 includes one of a plastic sealing process, compression molding, transfer molding, liquid sealing molding, vacuum lamination molding, spin coating molding, and electroplating molding, at which time the material of the pre-determined layer 60 is one of an epoxy resin, a silicone gel, a PBO, a BCB, silicon oxide, phosphor-silicone glass, fluorine-containing glass, and plated metal, and the specific thickness of the pre-determined layer 60 is set according to the actual needs. The thickness of the pre-determined layer 60 is set according to actual needs, and is not limited herein. The position of the first pre-passage hole 71 is located vertically above and aligned to the metal pad 20, and it is necessary to preset the metal pad 20 position vertically beforehand when preparing the first pre-passage hole 71, and the aperture of the first pre-passage hole 71 is the same as the aperture diameter of the polyimide perforation 74 formed ultimately, and the aperture size is less than or equal to 2 μm.

As shown in FIGS. 4 and 9, as an example, step S5 is then performed to form a second pre-passage hole 72 in the metal layer 40 aligned to the first pre-passage hole 71.

The second pre-passage hole 72 has the same aperture diameter as the first pre-passage hole 71, i.e. the same hole diameter as the polyimide hole 74 in the final formation, with an aperture size of less than or equal to 2 μm. The metal layer 40 is a single-layer structure of an Al layer or a stacked structure of a Ti layer and a Cu layer, and when the metal layer 40 is a single-layer structure of an Al layer, the second pre-passage holes 72 can be formed by etching with a dry process; when the metal layer 40 is a stacked structure of a Ti layer and a Cu layer, the second pre-passage holes 72 can be formed by etching with a wet process. The dry etching includes all gas types, e.g., O2, N2, AR, CF4, N2H2, etc., and the etching gas is selected mainly according to the substrate to be etched; the solution for wet process etching includes a debinding solution containing dimethyl sulfoxide, ethylene glycol, N-methyl-2-pyrrolidone, and tetramethylammonium hydroxide components. Both preparation methods can be used to form the second pre-passage hole 72, only that different formation methods are used for different materials of the metal layer 40, and the specific formation methods can be set according to the actual needs and are not limited herein.

As shown in FIGS. 4 and 10, as an example, step S6 proceeds with etching the polyimide layer 30 to form the third pre-passage hole 73 aligned to the second pre-passage hole 72, the third pre-passage hole 73 being located vertically aligned to and in direct contact with the metal pad 20. As an example, the first pre-passage hole 71, the second pre-passage hole 72, and the third pre-passage hole 73 are all on the same vertical line, and all three have the same aperture diameters, with the aperture diameters having dimensions less than or equal to 2μm. The method of preparing the polyimide perforations of this embodiment is also primarily directed to the small size of the polyimide hole 74, which makes the product design more complex and detailed, and greatly improves the chip performance, whereas most of the polyimide perforations of the prior art have a pore size of more than 2 μm.

As an example, the method of forming the polyimide hole 74 is dry etching the polyimide layer 30, the dry etching includes all gas types, for example, O2, N2, AR, CF4, N2H2, etc., and the etching gases are selected mainly according to the substrate to be etched, which can be set according to the actual needs, and is not limited herein. The dry etching process can reduce wastewater generation and environmental pollution, making it a greener technology.

As shown in FIGS. 4 and 11, as an example, a final step S7 is carried out to remove all structures on top of the polyimide layer 30 in order to form polyimide hole 74 on the polyimide layer 30.

The structure above the polyimide layer 30 at this time comprises the metal layer 40 and the pre-determined layer 60, which can be peeled off the pre-determined layer 60 first, or the pre-determined layer 60 can be etched with a dry etching process, and then the metal layer 40 can be etched by a dry etching or wet etching process. The removal methods include and are not limited to the above-described methods, as long as the removal requirements can be met, the specific settings can be made according to the actual needs, and no restriction is made herein.

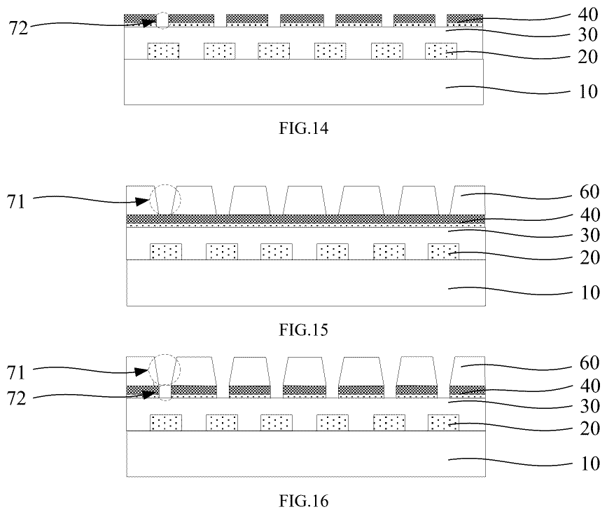

As shown in FIGS. 12 to 13, as an example, in step S4, the step of forming the pre-determined layer 60 comprises: first forming a patterned preset photoresist layer 50 on the metal layer 40, the preset photoresist layer 50 being located vertically above and aligned to the metal pad 20, the preset photoresist layer 50 having a diameter size of less than or equal to 2 μm (as shown in FIG. 12); plating a metal on the metal layer 40, then forming the pre-determined layer 60, the pre-determined layer 60 filling the gap between the pre-determined photoresist layers 50, the pre-determined layer 60 being flush with the top of the pre-determined photoresist layer 50 (as shown in FIG. 13); etching away all of the pre-determined photoresist layer 50 so as to form the first pre-pass-through hole 71 at the location of the pre-determined photoresist layer 50. It should be noted here that the position where graphically the pre-determined photoresist layer 50 is located, i.e. the position where the first pre-passage hole 71 is subsequently formed, graphically the pre-determined photoresist layer 50 shall be of cylindrical shape with a diameter dimension identical to that of the first pre-passage hole 71. The material of the pre-determined photoresist layer 50 is one or a combination of two or more of epoxy resin, silicone, PBO, BCB, silicon oxide, phosphor-silicon glass, and fluorine-containing glass, and the pre-determined photoresist layer 50 may be etched away using dry etching. The step of forming the pre-determined photoresist layer 50 comprises coating, exposing, and developing to form the pre-determined photoresist layer 50 having the same shape as the pre-determined shape of the first pre-passage hole 71. The subsequent process methods and types of materials are the same as in the above steps, which have been described in detail and will not be repeated here.

As shown in FIG. 14, as an example, in step S4, the pre-determined layer 60 is a photoresist layer, and the step of forming the photoresist layer includes coating, exposing, and developing, and etching the photoresist layer to form the first pre-passage holes 71, the first pre-passage holes 71 being located vertically above and aligned to the metal pads 20, and the size of the holes of the first pre-passage holes 71 being less than or equal to 2 μm, and in step S5, the step of forming the second pre-passage hole 72 is followed by the step of removing the pre-determined layer 60.

The step of forming the photoresist layer includes coating, exposing and developing, wherein the photoresist layer is formed first, and then the first pre-perforation 71 is etched on the photoresist layer; aligned to the first pre-perforation 71, the metal layer 40 is etched to form a second pre-perforation 72, and then the photoresist layer is removed, and the photoresist layer is made from one or a combination of one or two or more of epoxy resin, silica, PBO, BCB, silicon oxide, phosphor silica glass, and fluorine-containing glass, and dry etching can be used to etch away the photoresist layer. And a combination of one or more of fluorine-containing glass, the photoresist layer can be etched away using dry etching, at which time removing the photoresist layer reduces the burden of preparing the polyimide hole 74 in step S6, avoiding insufficiently fine preparation of the polyimide hole 74 due to too much structure above the polyimide layer 30.

As shown in FIGS. 15 to 16, as an example, in step S4, the material of the pre-determined layer is polyimide, and the step of forming the pre-determined layer 60 comprises a coating, exposing, developing, and curing, whereby the first pre-passage holes 71 are formed on the pre-determined layer 60 (as shown in FIG. 15), the first pre-passage holes 71 are located vertically directly above the metal pad 20, and the hole diameter of the first pre-passage holes 71 is size is less than or equal to 2 μm, in step S5, the formation of the second pre-passage hole 72 (as shown in FIG. 16) is followed by the step of removing the pre-determined layer 60.

The step of forming the pre-determined layer 60 includes coating, exposing, developing, and curing, and since the material of the pre-determined layer 60 is polyimide, the pre-determined layer 60 formed herein has already formed the first pre-passage holes 71, and the first pre-passage holes 71 formed herein and by this method will, to a certain extent, result in the presence of residues at the bottom, so that the lower profile of the first pre-passage holes 71 will be smaller than the upper profile of the first pre-passage holes 71. contour of the first pre-passage 71 is smaller than the upper contour. It should be noted herein that the metal layer 40 should be etched to form the second pre-passage hole 72 aligned to the hole diameter of the lower contour of the first pre-passage hole 71, the hole diameter of the lower contour of the first pre-passage hole 71 is the same as the hole diameter of the second pre-passage hole 72, and then the pre-determined layer 60 should be removed by dry etching, and then removing the pre-determined layer 60 relieves the burden of preparing the polyimide pre-passage hole 74 in step S6, avoiding the burden of preparing the polyimide pre-passage hole 74 due to too much structure above the polyimide layer 30. 74 and avoids the burden of preparing the polyimide hole 74 that are not fine enough due to too much structure above the polyimide layer 30.

### Embodiment 2

This embodiment provides a method of preparing a polyimide perforation according to one a specific embodiment, the method of preparing a polyimide perforation comprises the following steps:

providing the substrate 10 with the metal pads 20 attached to the surface, the substrate 10 preferably using a glass layer, which is less costly and is used to reduce the difficulty of the subsequent stripping process, the material of the metal pads 20 preferably being copper due to cost issues and conductivity, to become a copper solder pad.

The polyimide layer 30 is formed on the glass layer by a process of coating, full exposure, and curing, with the top of the polyimide layer 30 above the copper soldering disk, wherein the polyimide layer 30 is solid.

First a Ti layer and then a Cu layer is sputtered on the polyimide layer 30 sputtering to form a stacked structure of Ti/Cu layers.

Forming the pre-determined photoresist layer 50 on the Ti/Cu layer by coating, exposure and developing processes, the pre-determined photoresist layer 50 being located directly above the Ti/Cu layer vertically, the pre-determined photoresist layer 50 having a diameter of 1.8 μm, the pre-determined photoresist layer 50 being located at the position of the first pre-passage holes 71 later on with the same shape and height as the first pre-passage holes 71, and then electroplating metal Cu on the Ti/Cu layer to form an electroplated metal Cu layer, the electroplated metal Cu layer filling the gap between the pre-determined photoresist layer 50, the electroplated metal Cu layer being flush with the top of the pre-determined photoresist layer 50, wrapping the pre-determined photoresist layer 50, and then peeling off or etching off the pre-determined photoresist layer 50, thereby forming a first pre-passage hole 71 at a position of the pre-determined photoresist layer 50, the first pre-passage hole 71 being also a position of the first pre-passage hole 71 later, the first pre-passage hole 71 being the same shape and height as the first pre-passage hole 71 later, then forming a first pre-passage hole 71, the first pre-passage hole 71 having an hole size of 1.8 μm.

Aligned to the first pre-passage hole 71, a second pre-passage hole 72 is formed by etching the Ti/Cu layer using a wet etching process, and the second pre-passage hole 72 has the same hole size as that of the first pre-passage hole 71, both being 1.8 μm.

Aligned to the second pre-passage hole 72, a third pre-passage hole 73 is formed by etching the polyimide layer 30 using a dry etching process, the third pre-passage hole 73 is located vertically above and aligned to the Cu pad and is in direct contact with the Cu pad, the third pre-passage hole 73 is also of the same hole size as the second pre-passage hole 72 and both are 1.8 μm.

A dry etching process is first used to remove the remaining the plated metal Cu layer, and then a wet etching process is used to remove the remaining the Ti/Cu layer, ultimately obtaining the polyimide hole 74 on the polyimide layer 30.

### Embodiment 3

This embodiment provides a method of preparing a polyimide perforation according to a specific embodiment, the method of preparing a polyimide perforation comprises the following steps.

This embodiment differs from Embodiment 2 in the formation of the metal layer and the subsequent steps thereof, the previous steps are described in Embodiment 2 and will not be repeated herein.

Depositing a monolayer Al structure on the polyimide layer 30 by sputtering.

A photoresist layer is first formed on the Al layer by a process of coating, exposing, and developing, the material of the photoresist layer is an epoxy resin, and the photoresist layer is etched using a dry etching process to form the first pre-passage hole 71, the hole size of the first pre-passage hole 71 being 1.8 μm, and the first pre-passage hole 71 being disposed vertically directly above the Cu pad.

Aligned to the first pre-passage hole 71, a second pre-passage hole 72 is formed by etching the Al layer using a dry etching process, and then the remaining photoresist layer is etched using a dry etching process. Removing the remaining photoresist layer at this point eases the burden in preparing the polyimide hole 74 and avoids preparing the polyimide hole 74 in a less fine manner due to the structure above the polyimide layer 30 being too thick. The second pre-passage hole 72 has the same hole size as the first pre-passage hole 71, both being 1.8 μm.

Aligned to the second pre-passage hole 72, a third pre-passage hole 73 is formed by etching the polyimide layer 30 using a dry etching process, the third pre-passage hole 73 being disposed vertically directly above and in direct contact with the Cu pad. The third pre-passage hole 73 also has the same hole size as the second pre-passage hole 72, both being 1.8 μm.

Finally, a dry etching process is used to etch the remaining the Al layer to finally obtain the polyimide hole 74 on the polyimide layer 30.

All of the etching processes in this embodiment use dry etching, which can reduce wastewater generation and environmental pollution, making it a greener technology.

### Embodiment 4

This embodiment provides a specific embodiment of a method of preparing a polyimide perforation, the method of preparing a polyimide perforation comprising the following steps:

The difference between this embodiment and embodiment 2 lies in the steps behind the formation of the metal layer, the previous steps of which are described in embodiment 2 and will not be repeated herein.

On the Ti/Cu layer, the pre-determined layer 60 is formed by coating, exposure, developing and curing, etc., and the material of the pre-determined layer 60 is polyimide, and at this time the pre-determined layer 60 has already formed the first pre-passage hole 71, and on this substrate and the first pre-passage hole 71 formed in this way may cause to a certain extent the existence of residue at the bottom, making the lower contour of the first pre-passage hole 71 smaller than the upper contour, and the hole size of the lower contour of the first pre-passage hole 71 is about 1.8 μm. Contour is smaller than the upper contour, the hole size of the lower contour of the first pre-passage hole 71 is 1.8 μm, and the first pre-passage hole 71 is located vertically directly above the Cu pad.

Aligned to the hole diameter of the lower contour of the first pre-passage hole 71, a wet etching process is used to etch the Ti/Cu layer to form the second pre-passage hole 72; and then a dry etching process is used to etch the remaining the pre-determined layer 60, the material of which is a polyimide, then the burden in the preparation of the polyimide pre-passage holes 74 is alleviated, and the burden in preparing the polyimide pre-passage holes 74 is avoided, and the preparation of the polyimide pre-passage holes 74 is not fine enough due to the structure being too thick above the polyimide layer 30. 74 is not sufficiently fine. The aperture of the second pre-passage hole 72 is the same as the aperture of the lower contour of the first pre-passage hole 71, both being about 1.8 μm.

Aligned to the second pre-passage hole 72, the polyimide layer 30 is etched using a dry etching process to form the third pre-passage hole 73, the third pre-passage hole 73 being disposed vertically above and in direct contact with the Cu pad. The third pre-passage hole 73 also has the same hole size as the second pre-passage hole 72, both being about 1.8 μm.

Finally, a wet etching process is used to etch the remaining the Ti/Cu layer to finally obtain the polyimide hole 74 on the polyimide layer 30.

### Embodiment 5

The present embodiment provides a method of preparing a wafer-level semiconductor packaging structure, the method of preparing a wafer-level semiconductor packaging structure comprising a method of preparing a polyimide perforation as described in Embodiment 1.

In summary, the present invention provides a method of preparing a polyimide perforation, the method of preparing the polyimide perforation comprising the steps of: S1: providing a substrate with a metal pad attached to the surface; S2: forming a polyimide layer on the substrate, the polyimide layer being higher than the top of the metal pad; S3: forming a metal layer on the polyimide layer; S4: forming a pre-determined layer on the metal layer S4: forming a preset layer on the metal layer, and forming a first preset hole on the preset layer, the first preset hole being located directly above the metal pad vertically, and the first preset hole having an about size of less than or equal to 2 μm; S5: etching the metal layer to form a second preset hole aligned to the first preset hole; S6: etching the polyimide layer to form a third preset hole Aligned to the second preset hole, the third preset hole being located directly above the metal pad vertically, and being directly above the polyimide layer with the metal pad vertically directly above and in direct contact with the metal pad; S7: removing all structures above the polyimide layer to form a polyimide via on the polyimide layer. The present invention avoids the problem of residues at the bottom of small-sized polyimide perforations, making the top and bottom profiles of polyimide perforations basically consistent, and the preparation process refined, thus improving the yield of the product; the present invention is in the wafer-level semiconductor package, the smaller polyimide perforations can make the product design more complex and detailed, which greatly improves the performance of the chip. The present disclosure effectively addresses the limitations of existing technologies, making it highly valuable for industrial applications.

The embodiments described above serve merely as illustrative examples of the principles and effects of the present invention and are not intended to serve as limitations on the present invention. Persons skilled in the art may modify or alter these embodiments without departing from the spirit and scope of the present disclosure. Accordingly, all equivalent modifications or alterations accomplished by persons having ordinary knowledge of the art without departing from the spirit and technical ideas disclosed herein shall still be covered by the claims of the present invention.

1. A method of preparing a polyimide perforation, comprising steps of:
S1: provide a substrate having a metal pad on a surface of the substrate;
S2: forming a polyimide layer on the substrate, wherein a top surface of the polyimide layer is above the metal pad;
S3: forming a metal layer on the polyimide layer;
S4: forming a pre-determined layer on the metal layer, and forming a first pre-passage hole in the pre-determined layer, wherein the first pre-passage hole is disposed vertically above and aligned to the metal pad, and wherein the first pre-passage hole has an aperture size less than or equal to 2 μm;
S5: etching the metal layer to form a second re-passage hole aligned to the first pre-passage hole;
S6: etching the polyimide layer to form a third pre-passage hole, wherein the third pre-passage hole is aligned to the second pre-passage hole, wherein the third pre-passage hole is disposed vertically above and aligned to the metal pad, and wherein the third pre-passage hole is in direct contact with the metal pad; and
S7: removing the pre-determined layer, the metal layer and the polyimide layer from above the polyimide layer to form a polyimide perforation on the polyimide layer.

2. The method of preparing the polyimide perforation according to claim 1, wherein the first pre-passage hole, the second pre-passage hole, and the third pre-passage hole have a same hole size.

3. The method of preparing the polyimide perforation according to claim 1, wherein the step of forming the polyimide layer comprises: coating, full exposure, and curing.

4. The method of preparing the polyimide perforation according to claim 1, wherein: in step S4, forming the pre-determined layer comprises: first forming a patterned pre-determined photoresist layer on the metal layer, wherein the pre-determined photoresist layer is disposed vertically above and aligned to the metal pad, wherein the hole size of the pre-determined photoresist layer hole is less than or equal to 2 μm; disposing a pre-determined layer material on the metal layer to form the pre-determined layer, filling a gap between the pre-determined photoresist layers, wherein the pre-determined layer is flush with a top of the pre-determined photoresist layer;
etching away the pre-determined photoresist layer so as to form the first pre-passage hole in the pre-determined photoresist layer.

5. The method of preparing the polyimide perforation according to claim 1, wherein in step S4, the pre-determined layer is a photoresist layer, wherein the step of forming the pre-determined layer comprises coating, exposing and developing, and etching the pre-determined layer to form the first pre-passage hole, and wherein in step S5, the step of removing the pre-determined layer after forming the second pre-passage hole further comprises a step of removing the pre-determined layer.

6. The method of preparing the polyimide perforation according to claim 1, wherein in step S4, a material of the pre-determined layer is polyimide, the step of forming the pre-determined layer comprises coating, exposing, developing, and curing, wherein the first pre-passage hole is formed on the pre-determined layer, and in step S5, the step of formation the second pre-passage hole further comprises a step of removing the pre-determined layer.

7. The method of preparing the polyimide perforation according to claim 1, wherein a material of the metal pad is one or a combination of two or more of aluminum, copper, and gold.

8. The method of preparing the polyimide perforation according to claim 1, wherein the metal layer is a monolayer aluminum structure or a stacked structure of a titanium layer and a copper layer.

9. The method of preparing the polyimide perforation according to claim 1, wherein a step of forming a polyimide pre-passage hole is by dry etching of the polyimide layer.

10. A method of preparing a wafer-level semiconductor packaging structure, comprising the method of preparing the polyimide perforation according to claim 1.
